(19) United States
(12) Patent Application Publication
(10) Pub. No.: US 2020/0144428 A1
(43) Pub. Date: May 7, 2020

(54) HIGH-FREQUENCY ABSORPTION DIODE CHIP AND METHOD OF PRODUCING THE SAME

(71) Applicant: CHONGQING PINGWEI ENTERPRISE CO., LTD., Chongqing (CN)

(72) Inventors: XINGLONG WANG, CHONGQING (CN); SHUZHOU LI, CHONGQING (CN); LIANG CHEN, CHONGQING (CN); LI ZHANG, CHONGQING (CN); YIHU PAN, CHONGQING (CN)

(73) Assignee: CHONGQING PINGWEI ENTERPRISE CO., LTD., CHONGQING (CN)

(21) Appl. No.: 15/737,546

(22) PCT Filed: Jan. 17, 2017
(86) PCT No.: PCT/CN2017/071407

§ 371 Date: Dec. 26, 2019

(30) Foreign Application Priority Data
Jan. 16, 2017 (CN) 2017100288281

(51) Int. Cl. H01L 29/861; H01L 29/06; H01L 23/31; H01L 29/167; H01L 29/417; H01L 29/45; H01L 29/66; H01L 21/02; H01L 21/3065; H01L 21/027; H01L 21/265; H01L 21/285; H01L 21/3213

(52) U.S. Cl. CPC H01L 29/861; H01L 21/02164; H01L 23/3171; H01L 29/167; H01L 29/417; H01L 29/456; H01L 29/66136; H01L 21/02236; H01L 21/3065; H01L 21/0273; H01L 21/26513; H01L 21/2855; H01L 21/32133; H01L 29/0607; H01L 21/02532; H01L 21/02271; H01L 21/02129; H01L 29/0684

(57) ABSTRACT

A high-frequency absorption diode chip and a making method. The chip comprises a substrate; an epitaxial layer; a base region window; the base region window comprises a pressure point region and a partial pressure region; the epitaxial layer separates the pressure point region from the partial pressure region; a first ion diffusion layer is formed on the base region window; an emitting region window is provided on the first ion diffusion layer; a second ion diffusion layer is formed on the emitting region window; the upper surfaces of the first ion diffusion layer and the second ion diffusion layer in the pressure point region both are provided with a passivation layer; the upper surface of the first ion diffusion layer in the partial pressure region is provided with an oxide layer; both the oxide layer and the passivation layer extend to the upper surface of the epitaxial layer.

### TECHNICAL FIELD

The present invention relates to technical field of silicon chip production, and more particularly to a high-frequency absorption diode chip and a method of producing the same.

### Background

As for the diode used in a circuit for return circuit absorption, ordinary rectifier diodes are usually used when selecting power devices. The application frequency of an ordinary rectifier diode is generally below 50 kHz. As for an application environment of more than 60 kHz, it is difficult for ordinary rectifier diodes to achieve a complete absorption effect, and strong electromagnetic interference will be accompanied. The phenomenon of electromagnetic interference is more apparent in a RCD return circuit. At the same time, an absorption diode used specifically in an application environment of more than 60 kHz has not been reported in any documents.

### SUMMARY

In view of the disadvantages of the prior art described above, an object of the present invention is to provide a high-frequency absorption diode chip and a method of producing the same for solving the problems that achieving a complete absorption effect and overcoming the electromagnetic interference and other issues is difficult when a diode in the prior art is applied to an environment of more than 60 kHz.

In order to achieve the above object and other related purposes, a second aspect of the present invention is to provide a high-frequency absorption diode chip comprising a substrate, an epitaxial layer is formed on an upper surface of the substrate, a base region window is provided on the epitaxial layer, the base region window comprises a pressure point region and a partial pressure region located at the periphery of the pressure point region, the epitaxial layer separates the pressure point region from the partial pressure region, a first ion diffusion layer is formed in the base region window, an emitting region window is formed on the first ion diffusion layer, a second ion diffusion layer is formed in the emitting region window, the upper surfaces of the first ion diffusion layer and the second ion diffusion layer in the pressure point region both are provided with a passivation layer, the upper surface of the first ion diffusion layer in the partial pressure region is provided with a oxide layer, both the oxide layer and the passivation layer extend to the upper surface of the epitaxial layer, and the passivation layer separates the oxide layer from the first ion diffusion layer in the pressure point region.

In some embodiments of the present invention, the substrate is an N+ semiconductor, the epitaxial layer is an N− semiconductor, the first ion diffusion layer is a boron ion diffusion layer, and the second ion diffusion layer is a phosphorus ion diffusion layer.

In some embodiments of the present invention, the substrate is a P+ semiconductor, the epitaxial layer is a P− semiconductor, the first ion diffusion layer is a phosphorus ion diffusion layer, and the second ion diffusion layer is a boron ion diffusion layer.

In some embodiments of the present invention, the depth difference between the first ion diffusion layer and the second ion diffusion layer is 3-5 μm.

In some embodiments of the present invention, a surface metal layer is formed on the upper surface of the passivation layer.

In some embodiments of the present invention, a backside metal layer is formed on the lower surface of the substrate,

In some embodiments of the present invention, a thickness of the substrate is 215˜220 μm, a thickness of the epitaxial layer is great than or equal to 50 μm, a thickness of the oxide layer is 5000˜1000 Å, a thickness of the first ion diffusion layer is 6˜10 μm, a thickness of the second ion diffusion layer is 35 μm, a thickness of the surface metal layer is 3˜6 μm, and a thickness of the backside surface metal layer is 24 μm.

In some embodiments of the present invention, a thickness of the epitaxial layer is 50˜80 μm.

A second aspect of the present invention provides a method for producing a high-frequency absorption diode chip, and the method comprises at least the following steps:

1) oxidizing a substrate: selecting a semiconductor substrate, forming an epitaxial layer on the substrate, and forming an oxide layer on the epitaxial layer;

2) performing a first photo-etching: after forming a first photoresist layer on the oxide layer, etching the first photoresist layer and the oxide layer to expose the epitaxial layer, defining a pattern of the base region window, and removing the photoresist;

3) performing a first ion implantation: implanting ions along the base region window to form a first ion layer;

4) diffusing and oxidizing of the base region: diffusing and oxidizing the ion in the base region window, the ion of the first ion layer diffusing downward to form a first ion diffusion layer, and a first ion diffusion oxidation layer being formed on the upper surface of the first ion layer;

5) performing a second photo-etching: after forming the second photoresist layer on the oxide layer of the base region window, etching the second photoresist layer and the ion oxide layer to expose the first ion diffusion layer, and defining a pattern of the emitting region window;

6) performing a second ion implantation: implanting ion along the emitting region window to form a second a second ion layer;

7) diffusing and oxidizing of the emitting region: diffusing and oxidizing the ion in the emitting region window, the ion of the second ion layer being diffused downward to form a second ion diffusion layer, and a second ion oxidation layer being formed on the upper surface of the second ion layer;

8) performing passivation: removing all of the oxide layers in the pressure point region and a portion of the oxidation layer on the upper surface, closing to the pressure point region, of the epitaxial layer to expose a portion of the epitaxial layer and the entire pressure point region, forming a passivation layer on an upper surface of the entire chip;

9) performing positive metal evaporation: forming a surface metal layer on the upper surface of the passivation layer;

10) performing a third photo-etching: coating a photoresist layer on the surface metal layer, removing a portion of the metal layer and the passivation layer except for the pressure point region via etching, the passivation layer extending to the upper surface of the epitaxial layer, separating the oxide layer from the first ion diffusion layer in the pressure point region, then removing the photoresist layer;

11) performing backside metal evaporation: forming a backside metal layer on the backside of the substrate to produce the diode chip.

In some embodiments of the present invention, in step 1), the substrate is an N+ semiconductor or a P+ semiconductor.

In some embodiments of the present invention, in step 3) and step 6), before implanting ions, dry-oxygen oxidation is firstly performed; the oxidation temperature is 1100° C.; the time for oxidation is 60 minutes; the gas atmosphere thereof is N2+O2, especially, containing nitrogen of 70% volume and oxygen of 30% volume.

In some embodiments of the present invention, in step 3) and step 6), before implanting ions, dry-oxygen oxidation is firstly performed; a thickness of dry-oxygen oxidation is 5000˜10000 Å.

In some embodiments of the present invention, in step 1), when the substrate is an N+ semiconductor, the epitaxial layer is an N− semiconductor; the ion implanted in step 3) is boron; the ion implanted in step 6) is phosphorus; the energy of implanted boron ion is 60˜400 KeV; the dose thereof is 5*1012˜5*1014/cm−2; the energy of implanted phosphorus ion is 0.5˜7.5 MeV; and the dose thereof is 2*1012˜2*1013/cm−2; or in step 1), the substrate is a P+ semiconductor, the epitaxial layer is a P− semiconductor; the ion implanted in step 3) is phosphorus; and the ion implanted in step 6) is boron. The reference “+” in the present invention refers to heavy doping, and the reference “−” refers to light doping.

In some embodiments of the present invention, in step 4), the temperature of the diffusion oxidation is 1100±50° C., and the time for diffusion oxidation is 120±5 minutes. The diffusion furnace shielding gas contains 70% by volume of nitrogen and 30% by volume of oxygen. In some embodiments of the present invention, in step 7), the temperature of diffusion oxidation is 950±50° C., and the time for diffusion oxidation is 120±10 minutes. The diffusion furnace shielding gas contains 70% by volume of nitrogen and 30% by volume of oxygen.

In some embodiments of the present invention, the depth difference between the first ion diffusion layer formed in step 4) and the second ion diffusion layer formed in step 7) is a junction depth D; the junction depth D is 3-5 μm; the junction depth D determines the high-frequency frequency of a diode, and the high-frequency frequency thereof can reach 300-500 kHz.

In some embodiments of the present invention, in step 8), the method of forming the passivation layer is a chemical vapor deposition, and the passivation layer is PSG (Phosphosilicate Glass) and/or silicon oxide (SiO2).

In some embodiments of the present invention, in step 9), the surface metal layer is selected from one of aluminum, titanium, nickel or silver or a combination thereof, and the method of forming the surface metal layer is a physical vapor deposition.

In some embodiments of the present invention, in step 9), the surface metal layer has a thickness of 3˜6μm.

In some embodiments of the present invention, in step 10), the method further comprises: alloying the metal with silicon in a hydrogen atmosphere to obtain good ohmic contact.

In some embodiments of the present invention, in step 11), the backside portion of the substrate is firstly thinned to expose fresh silicon, and then the backside metal layer is formed.

In some embodiments of the present invention, in step 15), the backside metal layer is successive titanium, nickel and silver.

A third aspect of the present invention provides a use of the above diode chip in an RCD circuit.

As mentioned above, the high-frequency absorption diode chip and the method of producing the same of the present invention have the following beneficial effects: the high-voltage chip produced by the craft of the present invention is particularly suitable for peak absorption in an RCD circuit; at the same time, the leakage current of the chip formed by using the present process under a high-temperature of 125° C. is lower than that of a traditional diffusion diode chip by more than 50%. The defect rate of the chip disclosed in the present invention is very low, the process disclosed in the present invention is simple, and therefore the mass-production of the chip can be easily realized.

### BRIEF DESCRIPTION OF THE DRAWINGS

FIGS. 1-14 show schematic diagrams of the chip structures obtained in each step of the embodiment of the present invention.

FIG. 15 is a diagram showing the peak absorption of an ordinary rectifier according to embodiment 2 of the present invention.

FIG. 16 is a diagram showing the peak absorption of the diode chip produced by the present invention according to embodiment 2 of the present invention.

### DESCRIPTION OF COMPONENT REFERENCE NUMERALS

1—Substrate
2—Epitaxial layer
3—Oxide layer
4a—First photoresist layer
4b—Base region window
5—First ion layer
6a—First ion diffusion layer
6b—First ion oxidation layer
7a—Second photoresist layer
7b—Emitting region window
8—Second ion layer
8a—Second ion diffusion layer
8b—Second ion oxidation layer
9—Passivation layer
10—Surface metal layer
11—Pressure point region
12—Partial pressure region
13—Backside metal layer

### DETAILED DESCRIPTION OF THE PREFERRED EMBODIMENTS

The embodiments of present invention are described below with reference to specific embodiments. Those skilled in the art can easily understand other advantages and effects of the present invention from the content disclosed in this specification. The present invention may also be implemented or applied through other different specific implementation modes. Various modifications or variations may be made to all details in the description based on different points of view and applications without departing from the spirit of the present invention.

### Embodiment 1

The structure of the finished product of the diode chip shown in FIG. 14 comprises a substrate 1; an epitaxial layer 2 is formed on an upper surface of the substrate 1, and a base region window 4b is provided on the epitaxial layer 2; the base region window 4b comprises a pressure point region 11 and a partial pressure region 12 located at the periphery of the pressure point region 11; the partial pressure region 12 is a closed loop and is located at the periphery of the pressure point region 11; the epitaxial layer 2 separates the pressure point region 11 from the partial point region 12; a first ion diffusion layer 6a is formed on the base region window 4b; an emitting region window 7b is formed on the first ion diffusion layer 6a; a second ion diffusion layer 8a is formed in the emitting region window 7b; the depth difference between the first ion diffusion layer 6a and the second ion diffusion layer 8a is 3˜5 μm; the upper surfaces of the first ion diffusion layer 6a and the second ion diffusion layer 8a in the pressure point region 11 both are provided with a passivation layer 9; the upper surface of the first ion diffusion layer 6a in the partial pressure region 12 is provided with a oxide layer 3; both the oxide layer 3 and the passivation layer 9 extend to the upper surface of the epitaxial layer 2; and the passivation layer 9 separates the oxide layer 3 from the first ion diffusion layer 6a in the pressure point region 11.

As an example, the substrate 1 is an N+ semiconductor; the epitaxial layer 2 is an N− semiconductor; the first ion diffusion layer 6a is a boron ion diffusion layer; and the second ion diffusion layer 8a is a phosphorus ion diffusion layer; the finished product is an NPN diode chip.

As an example, the substrate 1 is a P+ semiconductor; the epitaxial layer 2 is a P− semiconductor; the first ion diffusion layer 6a is a phosphorus ion diffusion layer; and the second ion diffusion layer 8a is a boron ion diffusion layer; the finished product is a PNP diode chip.

As an example, a surface metal layer 10 is formed on the upper surface of the passivation layer 9; a passivation layer may also be formed on the upper surface of the surface metal layer 10.

As an example, a backside metal layer 13 is formed on the lower surface of the substrate 1.

As an example, a thickness of the substrate 1 is 215˜220 μm; a thickness of the epitaxial layer 2 is larger than or equal to 50 μm, preferably 50˜80 μm; a thickness of the oxide layer 3 is 5000˜10000 Å; a thickness of the first ion diffusion layer 6a is 6˜10μm; a thickness of the second ion diffusion layer 8a is 3˜5 μm; a thickness of the surface metal layer 10 is 3˜6 μm; and a thickness of the backside metal layer 13 is 2˜4 μm.

### Embodiment 2

A method of producing a NPN high-frequency absorption diode chip comprises the following steps:

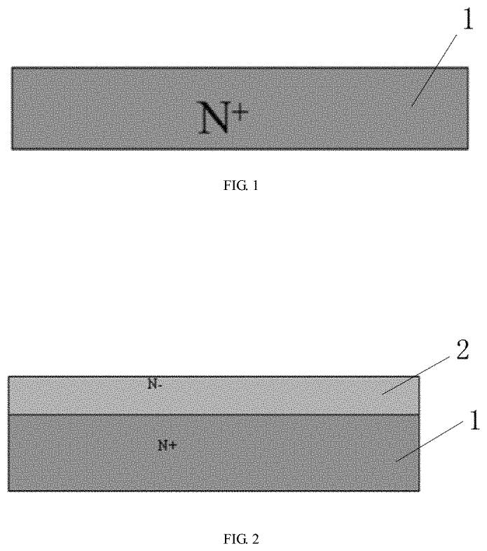

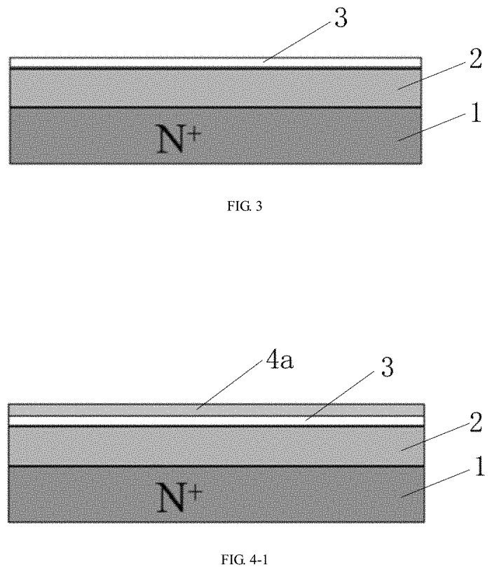

1) oxidizing a substrate: selecting a raw silicon chip, heavily doping the raw silicon chip with arsenic, and polishing the heavily doped silicon chip. In this embodiment, an N+ substrate 1 with a resistivity of β=15˜25 Ω*cm and a thickness of 215 μm is selected. The structure of the substrate 1 is shown in FIG. 1. A high resistance layer N−, i.e., the epitaxial layer 2, with a thickness of approximately 50 μm is grown according to the requirement of the product. The present embodiment has higher requirements to the uniformity of the resistivity and the lattice defects of the epitaxial layer 2. The direction of its lattice is uniformly orientated to avoid generating channel effect when implanting ion. The chip structure after epitaxial process is shown in FIG. 2. A layer of SiO2 (silicon oxide) is thermally grown on the surface of the high resistance layer N− by using a method of stream oxidation or a method of wet-oxygen oxidation method, and is used as base region diffusion sheltering layer, i.e., a oxide layer 3. Usually, a thickness of the oxide layer 3 is 5000˜10000 Å. In this embodiment, in order to ensure the selectable diffusion of the base region, a thickness of the oxide layer 3 is 8000 Å. The structure of the oxide layer 3 is shown in FIG. 3.

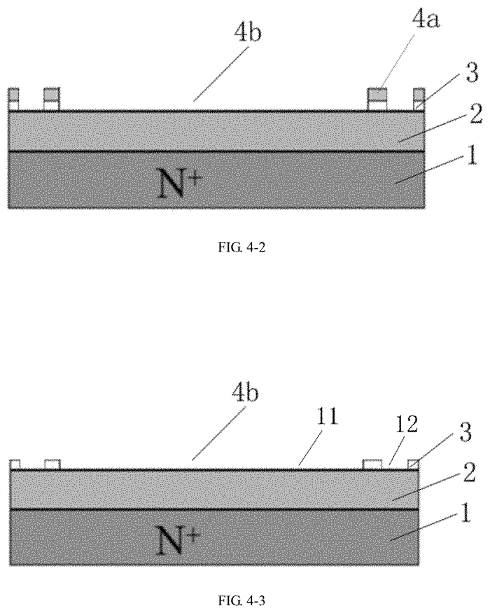

2) performing a first photo-etching: after a first photoresist layer 4a is formed on the oxide layer 3, a part of the oxide layer 3 is removed via etching, and a diagram of a base region window 4b is defined. The base region window 4b comprises pressure point region 11 and a partial pressure region 12 with annular shape is formed at the periphery of the pressure point region 11. The epitaxial layer 2 separates the pressure point region 11 from the partial pressure region 12. The base region window 4b is generated, and the oxide layer in the window is cleaned up via etching to expose the epitaxial layer 2, the oxide layer in the window has smooth margin and is burr-free. At the same time, the etching should be appropriated. The process comprises coating photoresist (as shown in FIG. 4-1), performing photo-etching (as shown in FIG. 4-2) and removing the photoresist (as shown in FIG. 4-3).

3) performing a first ion implantation: before implanting the ions, dry-oxygen oxidation is performed. Dry-oxidation layer is formed on the surface of the epitaxial layer 2 in the base region window 4b. The oxidation temperature thereof is 1100° C., the time for oxidization is 60 minutes, and the gas atmosphere thereof is N2+O2 (containing nitrogen of 70% volume and oxygen of 30% volume), such that the damage to the surface of the silicon caused by implanting ion can be reduced. A thickness of the oxidation is 5000˜10000 Å. In this embodiment, a thickness of the oxide layer 3 is 8000 Å. In addition, a higher conformity should be ensured when oxidization. As shown in FIG. 5, when using an ion implanter under a condition that energy is 200 KeV and a dose is 1.5*1014/cm−2, a first ion layer 5 is formed by implanting energetic boron (ions) into the silicon and the silicon dioxide (i.e., the exposed surface of the N− epitaxial layer 2). At this time, the depth of boron into the silicon is only 300˜800 Å, the boron does not have any activities, and the silicon does not have characteristics of PN junction.

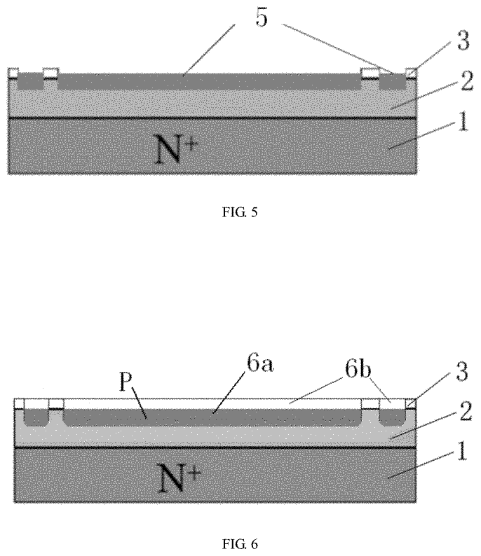

4) diffusing and oxidizing of the base region: the ions in the base region window 4b are diffused and oxidized. As shown in FIG. 6, boron ions in the first ion layer 5 are diffused downward to form a first ion diffusion layer 6a; a first ion oxide layer 6b is formed on the upper surface of the first ion layer 5; the upper surfaces of the epitaxial layer 2 and the oxide layer 3 are also correspondingly formed with an oxide layer. Specifically, after the nitrogen is deposited at 950° C. for 20 minutes and is oxidized at 1100° C. for 120 minutes, the diffusion furnace shielding gas contains 70% by volume of nitrogen and 30% by volume of oxygen, and the diffusion oxidation activates boron. As time goes by, boron atoms diffuse a certain depth in the silicon, i.e., about 8 μm, and form characteristics of PN junction. The PN junction is a collector junction, and it determines the voltage of BVcbo.

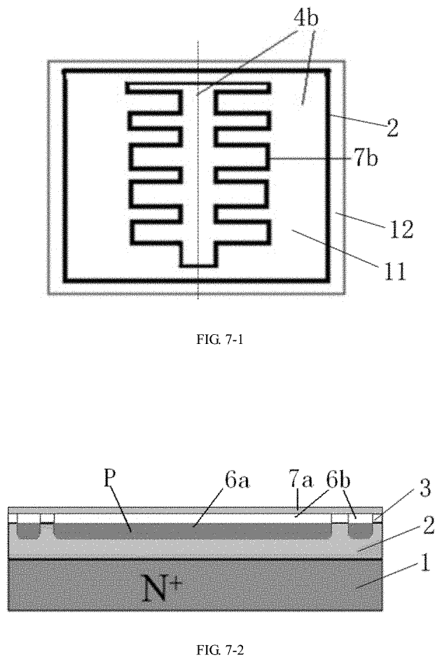

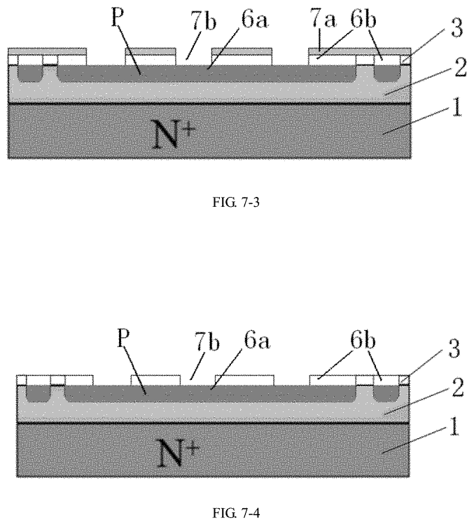

5) performing a second photo-etching: after the second photoresist layer 7a is formed on the first ion oxide layer 6b, the second photoresist layer 7a and the first ion oxide layer 6b are etched to expose the first ion diffusion layer 6a (i.e., boron diffusion layer); the diagram of the emitting region window 7b is defined (as shown in FIG. 7-1). In this embodiment, the chip has a square structure; the emitting region window 7b has an axisymmetric structure, and the symmetry axis of the emitting region window 7b is overlapped with that of the square chip. The process specifically includes coating the second photoresist (as shown in FIG. 7-2), performing a second photo-etching (as shown in FIG. 7-3) and removing the second photoresist (as shown in FIG. 7-4).

6) performing a second ion implantation: before implanting ions, a layer of dry oxidation is formed via dry-oxygen oxidation; a thickness of the layer of dry oxidation is about 8000 Å, the oxidation temperature thereof is 1100° C., the time for oxidization is 60 minutes, and the gas atmosphere thereof is N2+O2 (containing nitrogen of 70% volume and oxygen of 30% volume); then a second ion implantation is performed. As shown in FIG. 8, ions are implanted along the emitting region window 7b. Specifically, an ion implanter under energy of 1.5 MeV and a dose of 2*1012/cm−2 is used, and a second ion layer 8 is formed by implanting energetic phosphorus (ion) into the surface of the first ion diffusion layer 6a along the emitting region window 7b. At this time, the depth of phosphorus into the silicon is only 300˜800 Å, the phosphorus does not have any activities, and the thin silicon does not have characteristics of PN junction.

7) diffusing and oxidizing of the emitting region: the ions in the emitting region window 7b are diffused and oxidized; the phosphorus ions in the second ion layer 8 are diffused downward to form a second ion diffusion layer 8a; and a second ion oxide layer 8b is formed on the upper surface of the second ion layer 8; the corresponding upper surfaces of the epitaxial layer 2 and the oxide layer 3 both are formed with an oxide layer; specifically, the diffusion and oxidation are performed at 950° C. for 120 minutes, the diffusion furnace shielding gas contains 70% by volume of nitrogen and 30% by volume of oxygen, and the phosphorus is therefore activated. As time goes by, phosphorus atoms diffuses a certain depth in the silicon, i.e., about 4 μm, to form characteristics of PN junction. The PN junction is an emitting junction, it determines the voltage and amplification adjustment of BVebo, and the structure thereof is shown in FIG. 9. The depth difference between the first ion diffusion layer 6a formed in step 4) and the second ion diffusion layer 8a formed in step 7) is a junction depth D, the junction depth D is 3-5 μm, and the junction depth D determines the high-frequency frequency of the diode. The high-frequency frequency of the diode can reach 300-500 kHz, and the junction depth of the present embodiment is 4 μm.

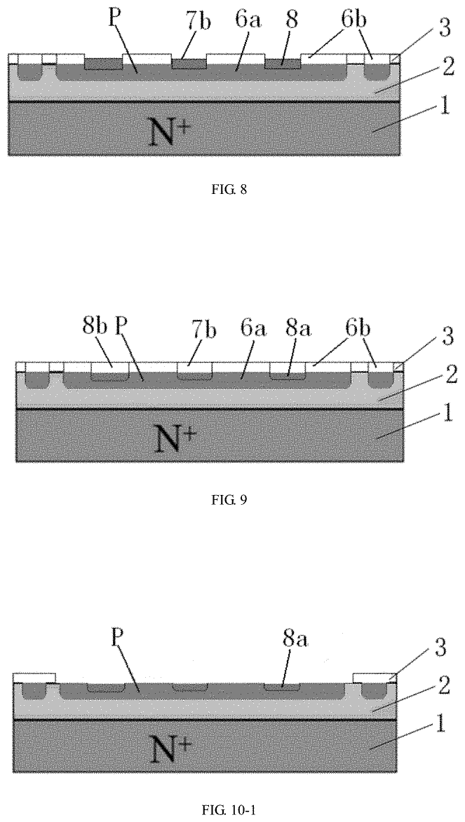

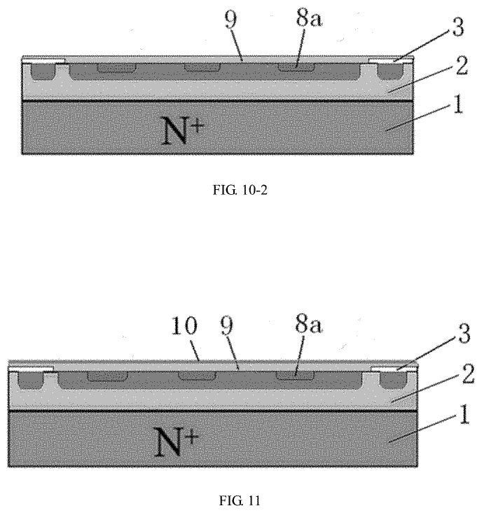

8) performing passivation: as shown in FIG. 10-1, the entire oxide layer of the pressure point region 11 and the portion of the oxide layer, closing to the pressure point region, on the upper surface of the epitaxial layer 2 are removed by using a hydrofluoric acid aqueous solution (weight ratio of hydrogen fluoride to water being 1:1) to expose a portion of the epitaxial layer 2 and the entire pressure point layer 11. The other portions of the oxide layer are remained. In FIG. 10-1, the oxide layer 3 is the remained oxide layer. As shown in FIG. 10-2, a passivation layer 9 is formed on the upper surface of the entire chip. The specific method of forming the passivation layer 9 is depositing PSG (Phosphosilicate Glas) and SiO2 (silicon oxide) by chemical vapor deposition (CVD) process and annealing at a temperature of 900±50° C. in a nitrogen atmosphere, such that the CVD layer is more denser .

9) Performing positive metal evaporation: as shown in FIG. 11, a surface metal layer 10 is formed on the upper surface (i.e., the front surface) of the passivation layer 9. The surface metal layer 10 may be a single aluminum layer, or layers sequentially formed by titanium layer and an aluminum layer from bottom to top, or layers sequentially formed by titanium layer, nickel layer and silver layer from bottom to top. The present embodiment uses an aluminum layer. Specifically, the aluminum layer is formed on the upper surface of the passivation layer 9 by a physical vapor deposition (PVD) method. A thickness of the aluminum layer is 3˜6 μm, specifically, 3 μm, 4 μm, 5 μm, 6 μm, etc. In this embodiment, a thickness of the aluminum layer is 4 μm.

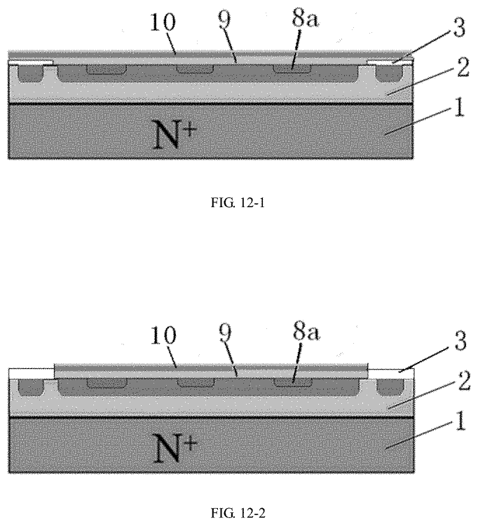

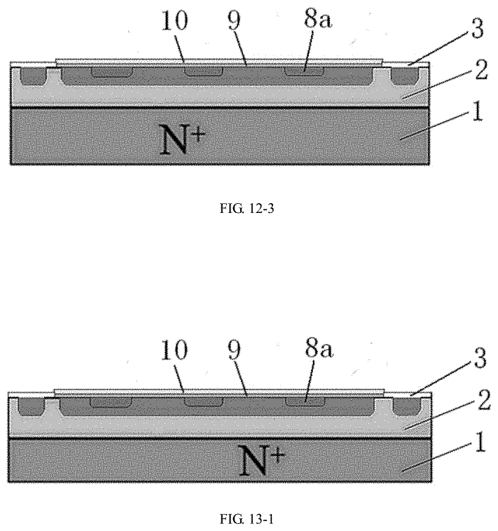

10) performing a third Photo-etching: a photoresist layer (as shown in FIG. 12-1) is coated on the surface metal layer 10; a portion of the aluminum and the passivation layer (as shown in FIG. 12-2) except for the pressure point region 11 are removed by etching, and the photoresist layer (as shown in FIG. 12-3) is then removed. The passivation layer 9 extends to the upper surface of the epitaxial layer 2, and the oxide layer 3 is separated from the first ion diffusion layer 6a in the pressure point region 11.

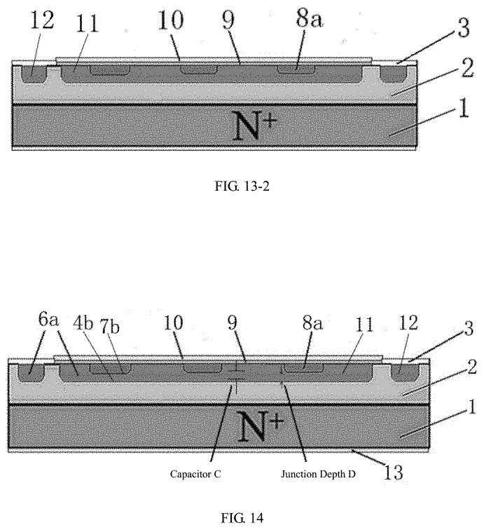

11) performing backside metal evaporation: as shown in FIG. 13-1, the backside of the N+ substrate is firstly thinned by using an etching solution; the composition of the etching solution is HNO3: HF: HAC: H2O=1:1:1:(20-25). The specific composition of the etching solution used in this embodiment is 1:1:1:20, and fresh silicon is exposed to be bonded with the metal; as shown in FIG. 13-2, the step is followed by evaporating backside contact Metal Ti, Ni, Ag to form the back of the metal layer 13 with a thickness of about 2 μm, and therefore a finished product is obtained. FIG. 14 shows a final finished structure, and the oxide layer 3 in FIG. 14 refers to the oxide composite layer finally formed after the above steps are processed.

The test results of the performance of the diode produced in this embodiment are as follows:

In the following table, IR refers to leakage current; IF refers to the model a diode, i.e., amperage; VR refers to the reverse voltage flow of a diode; and VF refers to forward voltage drop.

The following tables are explained as follows:

1: VF1 IF=0.100 A PW=0.5 mS Min=0.600V Max=0.800V (PRT) (VF1);

2: VF2 IF=0.500 A PW=0.5 mS Min=0.800V Max=1.100V (PRT) (VF2);

3: VR1 IB=10.0 uA PW=30 mS Min=650V Max=1000V VRG=1999V (PRT) (VR1);

4: VR2 IB=100.0 uA PW=30 mS Min=650V Max=1000V VRG=1999V (PRT) (VR2);

5: dVR1 Max=50V dVR=VR1-VR2 (PRT) (dVR1);

6: IR1 VR=650V PW=30 mS Max=0.080 uA IRG=9.999 uA (PRT) (IR1);

7: TRR1 IF=0.500 A IR=1.000 A IRR=250 mA Min=1300 nS Max=3000 nS Offset=0 nS (PRT) (TRR1).

TABLE 1

| | | [D1] | [D1] | [D1] | [D1] | [D1] | [D1] | [D1] |
|---|---|---|---|---|---|---|---|---|
| | | VF1 | VF2 | VR1 | VR2 | dVR1 | IR1 | TRR1 |
| NO | POL | (V) | (V) | (V) | (V) | (V) | (uA) | (nS) |
| 1 | N. | 0.762 | 0.984 | 668 | 677 | 9 | 0.02 | 1810 |
| 2 | N. | 0.659 | 0.983 | 673 | 683 | 10 | 0.017 | 1777 |
| 3 | N. | 0.659 | 0.982 | 677 | 683 | 6 | 0.016 | 1785 |
| 4 | N. | 0.659 | 0.984 | 675 | 685 | 10 | 0.02 | 1793 |
| 5 | R. | 0.662 | 0.983 | 680 | 685 | 5 | 0.018 | 1770 |
| 6 | R. | 0.661 | 0.98 | 658 | 671 | 13 | 0.019 | 1782 |
| 7 | N. | 0.659 | 0.976 | 680 | 686 | 6 | 0.02 | 1800 |
| 8 | N. | 0.659 | 0.98 | 674 | 683 | 9 | 0.021 | 1784 |
| 9 | R. | 0.661 | 0.982 | 666 | 675 | 9 | 0.021 | 1812 |
| 10 | R. | 0.662 | 0.982 | 669 | 676 | 7 | 0.019 | 1827 |
| 11 | N. | 0.659 | 0.987 | 672 | 680 | 8 | 0.021 | 1810 |
| 12 | N. | 0.765 | 0.986 | 674 | 681 | 7 | 0.021 | 1810 |
| 13 | R. | 0.661 | 0.983 | 673 | 684 | 11 | 0.022 | 1805 |
| 14 | N. | 0.661 | 0.976 | 671 | 682 | 11 | 0.017 | 1802 |
| 15 | R. | 0.662 | 0.977 | 674 | 683 | 9 | 0.017 | 1809 |
| 16 | R. | 0.66 | 0.979 | 673 | 683 | 10 | 0.021 | 1789 |
| 17 | N. | 0.658 | 0.976 | 679 | 686 | 7 | 0.019 | 1774 |
| 18 | N. | 0.659 | 0.99 | 678 | 685 | 7 | 0.017 | 1809 |
| 19 | R. | 0.661 | 0.982 | 668 | 680 | 12 | 0.018 | 1801 |
| 20 | R. | 0.66 | 0.976 | 670 | 681 | 11 | 0.018 | 1828 |
| 21 | N. | 0.659 | 0.981 | 681 | 684 | 3 | 0.022 | 1796 |
| 22 | R. | 0.662 | 0.979 | 674 | 685 | 11 | 0.021 | 1808 |
| 23 | R. | 0.661 | 0.978 | 679 | 685 | 6 | 0.02 | 1807 |
| 24 | N. | 0.659 | 0.983 | 682 | 684 | 2 | 0.02 | 1765 |
| 25 | N. | 0.763 | 0.979 | 674 | 680 | 6 | 0.018 | 1818 |
| 26 | N. | 0.763 | 0.979 | 672 | 681 | 9 | 0.018 | 1815 |
| 27 | N. | 0.762 | 0.977 | 677 | 683 | 6 | 0.019 | 1789 |
| 28 | R. | 0.66 | 0.976 | 674 | 682 | 8 | 0.018 | 1787 |
| 29 | R. | 0.661 | 0.996 | 675 | 682 | 7 | 0.02 | 1826 |
| 30 | R. | 0.662 | 0.982 | 675 | 686 | 11 | 0.023 | 1797 |
| 31 | N. | 0.659 | 0.978 | 667 | 678 | 11 | 0.023 | 1780 |
| 32 | N. | 0.66 | 0.977 | 675 | 682 | 7 | 0.018 | 1781 |
| 33 | R. | 0.661 | 0.979 | 672 | 680 | 8 | 0.021 | 1829 |
| 34 | N. | 0.659 | 0.984 | 673 | 682 | 9 | 0.022 | 1811 |
| 35 | R. | 0.66 | 0.977 | 669 | 678 | 9 | 0.019 | 1819 |
| 36 | R. | 0.663 | 0.98 | 665 | 676 | 11 | 0.018 | 1790 |
| 37 | N. | 0.765 | 0.984 | 675 | 682 | 7 | 0.019 | 1786 |
| 38 | R. | 0.661 | 0.981 | 678 | 686 | 8 | 0.021 | 1807 |
| 39 | N. | 0.659 | 0.978 | 673 | 682 | 9 | 0.02 | 1792 |
| 40 | R. | 0.662 | 0.978 | 676 | 686 | 10 | 0.021 | 1821 |
| 41 | R. | 0.661 | 0.98 | 678 | 685 | 7 | 0.02 | 1824 |
| 42 | N. | 0.66 | 0.977 | 668 | 677 | 9 | 0.019 | 1807 |
| 43 | R. | 0.661 | 0.977 | 678 | 685 | 7 | 0.023 | 1807 |
| 44 | N. | 0.659 | 0.977 | 671 | 679 | 8 | 0.02 | 1819 |
| 45 | N. | 0.66 | 0.98 | 677 | 684 | 7 | 0.022 | 1817 |
| 46 | N. | 0.66 | 0.976 | 678 | 684 | 6 | 0.019 | 1785 |
| 47 | R. | 0.661 | 0.979 | 671 | 682 | 11 | 0.024 | 1783 |
| 48 | R. | 0.661 | 0.987 | 670 | 679 | 9 | 0.021 | 1764 |
| 49 | N. | 0.659 | 0.981 | 668 | 679 | 11 | 0.023 | 1817 |
| 50 | N. | 0.663 | 1.054 | 674 | 681 | 7 | 0.023 | 1803 |
| 51 | R. | 0.662 | 1.015 | 680 | 691 | 11 | 0.023 | 1814 |
| 52 | R. | 0.661 | 0.989 | 669 | 678 | 9 | 0.02 | 1825 |
| 53 | R. | 0.661 | 0.99 | 672 | 680 | 8 | 0.018 | 1787 |
| 54 | N. | 0.765 | 0.99 | 672 | 679 | 7 | 0.04 | 1819 |
| 55 | N. | 0.659 | 0.981 | 675 | 684 | 9 | 0.021 | 1809 |
| 56 | R. | 0.661 | 0.977 | 659 | 671 | 12 | 0.023 | 1836 |
| 57 | N. | 0.659 | 0.987 | 680 | 682 | 2 | 0.02 | 1773 |
| 58 | R. | 0.662 | 0.979 | 668 | 681 | 13 | 0.019 | 1813 |
| 59 | N. | 0.659 | 0.98 | 678 | 685 | 7 | 0.021 | 1791 |
| 60 | R. | 0.662 | 0.988 | 675 | 687 | 12 | 0.02 | 1820 |
| 61 | R. | 0.66 | 0.983 | 678 | 687 | 9 | 0.021 | 1818 |
| 62 | N. | 0.659 | 0.98 | 679 | 686 | 7 | 0.02 | 1794 |
| 63 | N. | 0.657 | 0.98 | 673 | 683 | 10 | 0.019 | 1771 |
| 64 | R. | 0.661 | 0.994 | 674 | 682 | 8 | 0.019 | 1825 |
| 65 | N. | 0.659 | 0.984 | 670 | 681 | 11 | 0.021 | 1782 |
| 66 | N. | 0.659 | 0.995 | 673 | 684 | 11 | 0.023 | 1800 |
| 67 | N. | 0.658 | 0.981 | 679 | 685 | 6 | 0.023 | 1799 |
| 68 | N. | 0.658 | 0.997 | 667 | 678 | 11 | 0.021 | 1780 |
| 69 | R. | 0.661 | 0.98 | 666 | 679 | 13 | 0.024 | 1780 |
| 70 | R. | 0.662 | 0.991 | 682 | 687 | 5 | 0.018 | 1813 |
| 71 | N. | 0.662 | 0.982 | 677 | 686 | 9 | 0.021 | 1794 |
| 72 | N. | 0.66 | 0.99 | 674 | 684 | 10 | 0.02 | 1789 |
| 73 | R. | 0.661 | 0.981 | 672 | 682 | 10 | 0.02 | 1798 |
| 74 | R. | 0.661 | 0.981 | 677 | 685 | 8 | 0.02 | 1812 |
| 75 | N. | 0.66 | 0.983 | 673 | 681 | 8 | 0.019 | 1769 |
| 76 | N. | 0.661 | 0.984 | 679 | 686 | 7 | 0.022 | 1815 |
| 77 | N. | 0.66 | 0.983 | 677 | 684 | 7 | 0.02 | 1770 |
| 78 | N. | 0.766 | 0.979 | 676 | 686 | 10 | 0.023 | 1821 |
| 79 | R. | 0.661 | 0.975 | 675 | 682 | 7 | 0.019 | 1792 |
| 80 | N. | 0.658 | 0.977 | 677 | 685 | 8 | 0.022 | 1828 |
| 81 | R. | 0.661 | 0.982 | 678 | 685 | 7 | 0.02 | 1789 |
| 82 | R. | 0.661 | 0.987 | 667 | 679 | 12 | 0.021 | 1817 |
| 83 | N. | 0.657 | 0.976 | 679 | 688 | 9 | 0.02 | 1811 |
| 84 | N. | 0.659 | 0.99 | 678 | 686 | 8 | 0.021 | 1807 |
| 85 | N. | 0.658 | 0.973 | 672 | 683 | 11 | 0.019 | 1783 |
| 86 | N. | 0.658 | 0.981 | 682 | 692 | 10 | 0.025 | 1808 |
| 87 | N. | 0.767 | 0.982 | 679 | 686 | 7 | 0.018 | 1816 |

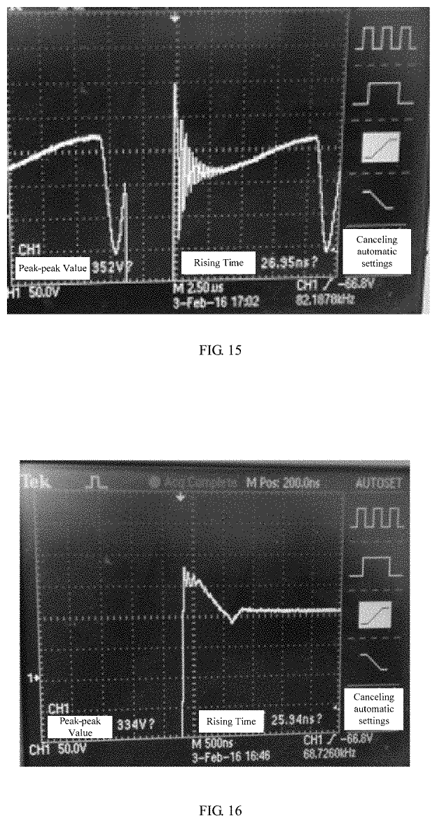

The performance of RCD loop peak absorption of a charger of 12V2A and the performance of the VDS parameters of a parallel MOSFET test are as follows: A, the peak absorption of an ordinary rectifier (1N4007) is VDS=352V, and the test results are shown in FIG. 15; B, the peak absorption of the product disclosed in the present invention is VDS=148V, and the test results are shown in FIG. 16.

In summary, the chip produced by the present invention is particularly suitable for the peak absorption of a RCD circuit having a current of 0.5˜5 Å according to different layout design due to the special capacitance characteristic formed by the double-layer PN junction. At the same time, the leakage current of the chip formed by using the present process under a high-temperature of 125° C. is lower than that of a traditional diffusion diode chip by more than 50%. The defect rate of the chip disclosed in the present invention is very low, the process disclosed in the present invention is simple, and therefore the mass-production of the chip can be easily realized.

The above-mentioned examples merely illustrate the principle of the present invention and its efficacy, but are not intended to limit the present invention. Those skilled in the art may make modifications or changes to the above embodiments without departing from the spirit and scope of the present invention. Therefore, all equivalent modifications or changes made by those skilled in the art without departing from the spirit and technical idea disclosed in the present invention should still be covered by the claims of the present invention.

1. A high-frequency absorption diode chip, comprising a substrate (1), characterized in that an epitaxial layer (2) is formed on an upper surface of the substrate (1), a base region window (4b) is provided on the epitaxial layer (2), the base region window (4b) comprises a pressure point region (11) and a partial pressure region (12) located at a periphery of the pressure point region (11), the epitaxial layer (2) separates the pressure point region (11) from the partial pressure region (12), a first ion diffusion layer (6a) is formed in the base region window (4b), an emitting region window (7b) is formed on the first ion diffusion layer (6a), a second ion diffusion layer (8a) is formed in the emitting region window (7b), upper surfaces of the first ion diffusion layer (6a) and the second ion diffusion layer (8a) in the pressure point region (11) both are provided with a passivation layer (9), an upper surface of the first ion diffusion layer (6a) in the partial pressure region (12) is provided with a oxide layer (3), both the oxide layer (3) and the passivation layer (9) extend to an upper surface of the epitaxial layer (2), and the passivation layer (9) separates the oxide layer (3) from the first ion diffusion layer (6a) in the pressure point region (11).

2. The diode chip according to claim 1, characterized in that the substrate (1) is an N+ semiconductor, the epitaxial layer (2) is an N− semiconductor, the first ion diffusion layer (6a) is a boron ion diffusion layer, and the second ion diffusion layer (8a) is a phosphorus ion diffusion layer; or the substrate (1) is a P+ semiconductor, the epitaxial layer (2) is a P− semiconductor, the first ion diffusion layer (6a) is a phosphorus ion diffusion layer, and the second ion diffusion layer (8a) is a boron ion diffusion layer.

3. The diode chip according to claim 1, characterized in that the depth difference between the first ion diffusion layer (6a) and the second ion diffusion layer (8a) is 3-5 μm.

4. The diode chip according to claim 1, characterized in that a surface metal layer (10) is formed on an upper surface of the passivation layer (9), a backside metal layer (13) is formed on the lower surface of the substrate (1), preferably, the surface metal layer (10) is selected from more of aluminum, titanium, nickel or silver or a combination thereof, and the backside metal layer (13) is, successive titanium, nickel and silver.

5. The diode chip according to claim 1, characterized in that a thickness of the substrate (1) is 215˜220 μm, a thickness of the epitaxial layer (2) is great than or equal to 50 μm, a thickness of the oxide layer (3) is 5000˜1000 Å, a thickness of the first ion diffusion layer (6a) is 6˜10 μm, a thickness of the second ion diffusion layer (8a) is 3˜5 μm, a thickness of the surface metal layer (10) is 3˜6 μm, and a thickness of the backside surface metal layer (13) is 2˜4 μm.

6. A method for producing a high-frequency absorption diode chip, characterized in that the method comprises at least the following steps:
1) oxidizing a substrate: selecting a semiconductor substrate (1), forming an epitaxial layer (2) on the substrate (1), and forming an oxide layer (3) on the epitaxial layer (2);
2) performing a first photo-etching: after forming a first photoresist layer (4a) on the oxide layer (3), etching the first photoresist layer (4a) and the oxide layer (3) to expose the epitaxial layer (2), defining a pattern of the base region window (4b), and removing the photoresist;
3) performing a first ion implantation: implanting ions along the base region window (4b) to form a first ion layer (5);
4) diffusing and oxidizing of the base region: diffusing and oxidizing the ions in the base region window (4b), the ions of the first ion layer (5) being diffused downward to form a first ion diffusion layer (6a), and a first ion oxidation layer (6b) being formed on an upper surface of the first ion layer (5);
5) performing a second photo-etching: after forming a second photoresist layer (7a) on the oxide layer of the base region window (4b), etching the second photoresist layer (7a) and the first ion oxidation layer (6a) to expose the first ion diffusion layer (6a), and defining a pattern of the emitting region window (7b);
6) performing a second ion implantation: implanting ions along the emitting region window (7b) to form a second ion layer (8);
7) diffusing and oxidizing of the emitting region: diffusing and oxidizing the ions in the emitting region window (7b), the ions of the second ion layer (8) being diffused downward to form a second ion diffusion layer (8a), and a second ion oxidation layer (8b) being formed on the upper surface of the second ion layer (8);
8) performing passivation: removing all of the oxide layer in the pressure point region (11) and a portion of the oxide layer on the upper surface, closing to the pressure point region (11), of the epitaxial layer (2) to expose a portion of the epitaxial layer and the entire pressure point region (11), and forming a passivation layer (9) on an upper surface of the entire chip;
9) performing positive metal evaporation: forming a surface metal layer (10) on the upper surface of the passivation layer (9);
10) performing a third ion implantation: coating a photoresist layer on the surface metal layer (10), removing a portion of the metal layer and the passivation layer except for the pressure point region (11) via etching, the passivation layer (9) extending to the upper surface of the epitaxial layer (2), separating the oxide layer (3) from the first ion diffusion layer (6a) in the pressure point region (11), then removing the photoresist layer;
11) performing backside metal evaporation: forming a backside metal layer (13) on the backside of the substrate (1) to produce the diode chip.

7. The method for producing the high-frequency absorption diode chip according to claim 6, characterized in that: in step 1), when the substrate (1) is an N+ semiconductor, the epitaxial layer (2) is an N− semiconductor; the ion implanted in step 3) is boron; the ion implanted in step 6) is phosphorus; the energy of implanted boron ion is 60˜400 KeV; the dose thereof is 5*10¹²˜5*10¹⁴/cm⁻²;
the energy of implanted phosphorus ion is 0.5˜7.5 MeV, and the dose thereof is 2*10¹²˜2*10¹³/cm⁻².

8. The method for producing the high-frequency absorption diode chip according to claim 6, characterized in that: in step 1), when the substrate (1) is a P+ semiconductor, the epitaxial layer (2) is a P− semiconductor, the ion implanted in step 3) is phosphorus, and the ion implanted in step 6) is boron.

9. The method for producing the high-frequency absorption diode chip according to claim 6, characterized in that: the depth difference between the first ion diffusion layer (6a) formed in step 4) and the second ion diffusion layer (8a) formed in step 7) is a junction depth D, and the depth of the junction depth D is 3˜5 μm.

10. Use of the diode chip according to claim 1 in a RCD circuit.
